(19) United States
(12) Patent Application Publication
(10) Pub. No.: US 2026/0171976 A1
(43) Pub. Date: Jun. 18, 2026

(54) LOW POWER BROADBAND GAIN AMPLIFIER

(71) Applicant: BeRex Corporation Co., Ltd, Seoul (KR)

(72) Inventor: Byeong Seok YOO, Seoul (KR)

(73) Assignee: BeRex Corporation Co., Ltd, Seoul (KR)

(21) Appl. No.: 19/175,785

(22) Filed: Apr. 10, 2025

(30) Foreign Application Priority Data
Dec. 16, 2024 (KR) 10-2024-0187575

(51) Int. Cl. H03F 1/30; H03F 1/56

(52) U.S. Cl. CPC H03F 1/302; H03F 1/56; H03F 2200/451

(57) ABSTRACT

The present disclosure relates to a low power broadband gain amplifier and includes a signal amplification part; a bias part; and an output stabilization part. The signal amplifier includes: a first transistor which amplifies an input signal, in which a radio frequency (RF) output is connected to the first matching part and an RF input is connected to the second matching part; a third resistor which is connected to an emitter of the first transistor and ensures heat dissipation and operational stability of the first transistor; and a second transistor which is connected to the RF output and the first matching part, preserves quality of a signal amplified from the first transistor and additionally amplifies a gain. The present disclosure provides very uniform gain amplification performance across a broadband operating band from 10 MHz to 6 GHz at low power levels of 0.2 W or less.

### BACKGROUND

### Field

The present disclosure relates to a gain amplifier, and more particularly, to a low power broadband gain amplifier which provides very uniform gain amplification performance over a broadband operating band from 10 MHz to 6 GHz at low power of 0.2 W or less.

### Description of the Related Art

In recent years, the keyword in communication systems is ultra-high-speed, large-capacity data transmission. Although ultra-high frequency communication systems such as fifth generation (5G) and sixth generation (6G) communications have the advantage of being able to increase data transmission rates using wide bandwidths, this comes with the challenge of having to design circuits with wide operating bandwidths.

Generally, low power broadband gain amplifiers are essential in 5G and 6G networks.

Such low power broadband gain amplifiers enable fast, efficient data transmission by increasing data rates and throughput.

Also, low power broadband gain amplifiers may extend battery life and improve power efficiency by maintaining high performance while reducing power consumption.

Wide-range communication enables long-distance communication and increases network reliability by maintaining stable performance in various environments.

Low power broadband gain amplifiers may satisfy these diverse network requirements, providing network scalability.

For these reasons, low power broadband gain amplifiers are essential for future wireless communication technology development.

### Documents in Related Art

### Patent Documents

(Patent Document 0001) Korean Registration Patent No. 10-0597770, DARLINGTON CIRCUIT, PUSH-PULL POWER AMPLIFIER AND INTEGRATED CIRCUIT DEVICE OBTAINED BY INTEGRATING THESE: This patent relates to an integrated circuit device including a Darlington circuit and a push-pull power amplifier and has a structure in which a first transistor receives an input signal as a bias current and amplifies the input signal and a second transistor generates an output current. In addition, this patent proposes a configuration in which amplification characteristics is improved by reducing distortion by connecting a resistor and a voltage source to an emitter.

(Patent Document 0002) Korean Registration Patent No. 10-1552896, BROADBAND AMPLIFIER: This patent proposes an amplifier which converts a single-ended input signal into a differential signal and improves broadband characteristics by reducing a magnitude and phase mismatch of a signal through a mismatch reduction part. Furthermore, this patent implements a low-noise amplifier suitable for broadband communications by improving input matching through a feedback circuit using a transformer.

(Patent Document 0003) U.S. Pat. No. 5,410,284, ADAPTIVE BANDWIDTH AMPLIFIER: This patent proposes an adaptive bandwidth amplifier to solve broadband noise issues in an intermediate frequency (IF) amplifier of a wireless communication receiver. Particularly, this patent includes a method of improving communication quality by controlling a frequency response and improving a signal-to-noise ratio (SNR) through a circuit design including a Darlington structure.

(Patent Document 0004) Korean Registration Patent No. 10-0200533, DARLINGTON AMPLIFIER CIRCUIT FOR OVERCURRENT CONTROL: This patent proposes a Darlington amplifier circuit for overcurrent control which controls a current flowing through a semiconductor element in accordance with a base voltage of a Darlington amplifier, thereby protecting a semiconductor element even when an excessive current is applied from the outside. Particularly, this patent includes a method for improving stability and gain characteristics in a high frequency band through a switching time adjustment part and an overcurrent branch part.

### SUMMARY

The present disclosure is directed to providing a low power broadband gain amplifier which stably and uniformly amplifies a signal of 100 MHz band or higher using a high-order modulation method in a radio frequency (RF) high-frequency band and an intermediate frequency (IF) low-frequency band under the condition of power consumption of 0.2 W.

A low power broadband gain amplifier according to the characteristics of the present disclosure for achieving the above purpose includes:
a signal amplifier which amplifies and processes an input signal;
a bias part which provides a bias current for operating the signal amplifier part; and
an output stabilization part which attenuates and transmits an output signal of the signal amplifier part.

The low power broadband gain amplifier further includes:
a first matching part which is connected to an output terminal of the signal amplifier; and
a second matching part which is connected to an input terminal of the signal amplifier.

In the low power broadband gain amplifier, the bias part includes:
a first resistor which is connected to a radio frequency (RF) output and the first matching part, is connected to the first transistor and the output stabilization part, and is connected to an RF input and the second matching part;
a diode which is connected to the first resistor, is connected to the RF input and the second matching part, and is connected to a second resistor connected to a common ground; and
a second resistor which is connected to the diode and is connected to a common ground.

In the low power broadband gain amplifier, the signal amplifier part includes:
a first transistor which amplifies an input signal, in which the RF output is connected to the first matching part and the RF input is connected to the second matching part;
a third resistor which is connected to an emitter of the first transistor and ensures heat dissipation and operational stability of the first transistor;
a second transistor which is connected to the RF output and the first matching part, preserves quality of a signal amplified from the first transistor, and additionally amplifies a gain;
a first regulator which is connected to an emitter of the second transistor, secures heat dissipation and operational stability of the second transistor, suppresses low-frequency oscillation to reduce operational instability, and uniformly adjusts flatness of amplification gain for each frequency; and
a second regulator which suppresses high-frequency oscillation of the first transistor to reduce instability of operation and is capable of evenly adjusting flatness of amplification gain for each frequency.

In the low power broadband gain amplifier, the output stabilization part includes:
a fourth resistor which is connected to the first matching part connected to the RF output and is connected to the first resistor; and
a first capacitor which is connected to the fourth resistor and the first transistor and is connected to the first resistor and the diode.

In the low power broadband gain amplifier, the first regulator improves thermal stability and bias stability of the second transistor using the fifth resistor.

In the low power broadband gain amplifier, the second regulator is composed of a combination of an inductor and a sixth resistor.

In the low power broadband gain amplifier, the bias part allows additional series connection of diodes to compensate for a voltage drop due to a change in temperature in the circuit, thereby stabilizing a change in driving current due to a change in temperature.

With the above-described configuration, in an example embodiment of the present disclosure, it is possible to implement a gain amplifier within a wide operating band from a low-frequency IF band to a high-frequency RF band.

Also, according to an example embodiment of the present disclosure, it is possible to achieve a uniform gain amplification of 13 dB over a wide operating band from a low-frequency IF band to a high-frequency RF band.

Furthermore, according to an example embodiment of the present disclosure, it is possible to further increase a gain amplified from 3.0 gigahertz (GHz) to 4.7 GHz.

Moreover, according to an example embodiment of the present disclosure, it is possible to implement a gain amplifier having an idle current performance of a level of 50 milliamperes (mA) under a 3.3 voltage (V) bias voltage condition.

### BRIEF DESCRIPTION OF THE DRAWINGS

FIG. 1 is a diagram showing a low power broadband gain amplifier according to a first example embodiment of the present disclosure.

FIG. 2 is a diagram showing a low power broadband gain amplifier according to a second example embodiment of the present disclosure.

FIG. 3 is a diagram showing a low power broadband gain amplifier according to a third example embodiment of the present disclosure.

FIG. 4 is a diagram showing a circuit diagram of the low power broadband gain amplifier according to the third example embodiment of the present disclosure.

FIG. 5 shows a response for each frequency of an amplifier configured of a Darlington circuit that is a basic structure of the first example embodiment of the present disclosure.

FIG. 6 shows a response for each frequency of a gain amplifier to which a first regulator is applied in the second example embodiment of the present disclosure.

FIG. 7 shows a response for each frequency of a gain amplifier to which both the first regulator and a second regulator are applied in the third example embodiment of the present disclosure.

### DETAILED DESCRIPTION

An example embodiment of the present disclosure will be described in detail below with reference to the attached drawings so that a person having ordinary skill in the art to which the present disclosure belongs may easily practice the present disclosure. Here, the present disclosure may be implemented in many different forms and is not limited to an example embodiment described herein. And, in order to clearly explain the present disclosure, parts in the drawings which are not related to the explanation have been omitted and the same constituent elements are denoted by the same drawing symbols throughout the specification.

When a part of a specification is said to “include” a constituent element, this does not mean that it excludes other constituent elements, but rather that it may include other constituent elements, unless otherwise stated.

The present disclosure may be implemented in many different forms and is not limited to an example embodiment described herein and parts of the drawings which are not relevant to the description are omitted.

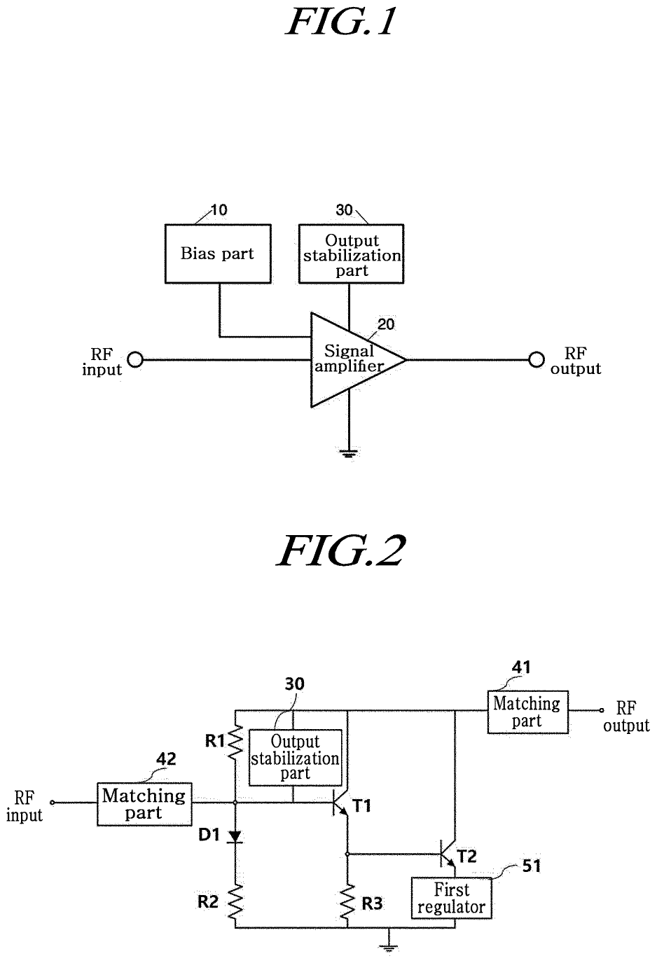

FIG. 1 is a diagram showing a low power broadband gain amplifier according to a first example embodiment of the present disclosure.

The gain amplifier according to the first example embodiment of the present disclosure includes
a signal amplifier 20 which amplifies and processes an input signal;
a bias part 10 which provides a bias current for operating the signal amplifier 20; and
an output stabilization part 30 which attenuates and transmits an output signal of the signal amplifier 20.

FIG. 2 is a diagram showing a low power broadband gain amplifier according to a second example embodiment of the present disclosure.

Referring to FIG. 2, the low power broadband gain amplifier according to the second example embodiment of the present disclosure includes a self-bias structure in the bias part 10 and a diode D1 for compensating for a voltage drop due to a temperature change. The diode D1 may be additionally connected in accordance with a degree of temperature change.

The signal amplifier part 20 has a high current gain due to the emitter-base connection of two transistors. In order to stabilize the heat dissipation generated in the transistor due to the operating current, a resistor is connected to the ground at the emitter-base connection and the same applies to the first regulator 51 for the same purpose.

In addition, matching parts 41 and 42 are added to each input and output part to reduce signal loss.

The output stabilization part 30 may suppress excessive oscillation in the low-frequency band by controlling the frequency response characteristics to reduce the high gain in the low-frequency band.

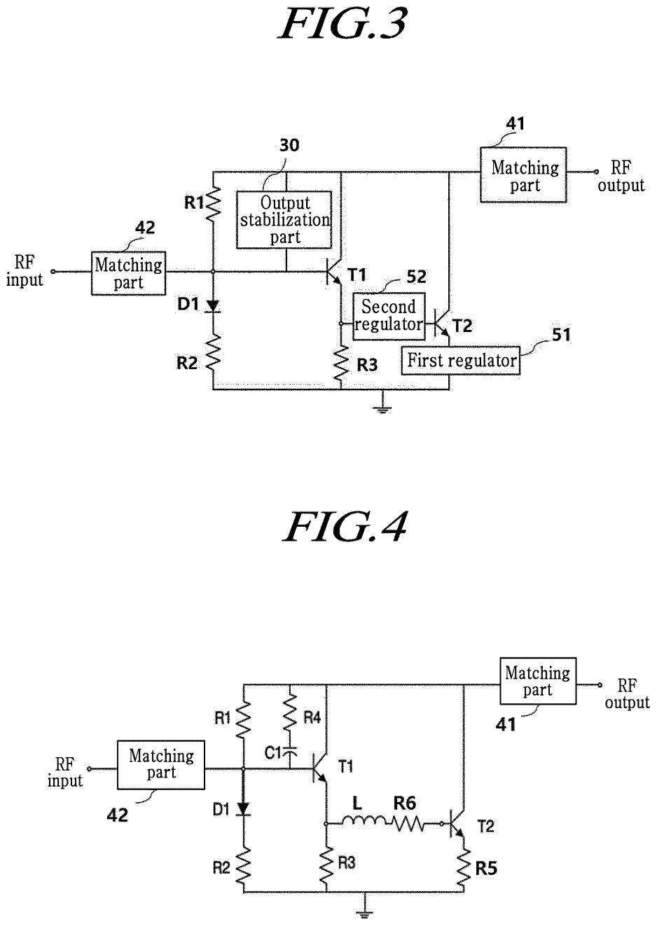

FIG. 3 is a diagram showing a low power broadband gain amplifier according to a third example embodiment of the present disclosure.

Referring to FIG. 3, the low power broadband gain amplifier according to the third example embodiment of the present disclosure additionally applies a second regulator 52 to the gain amplifier according to the second example embodiment of FIG. 2.

The second regulator 52 may further increase the amplification gain by improving the response at high frequencies, resulting in a more consistent amplification gain over a wider operating band.

In various example embodiments of the present disclosure, the radio frequency (RF) input and the RF output may be referred to as input and output sections, respectively.

According to an example embodiment of the present disclosure, a low power broadband gain amplifier receives bias power from an RF output part and generates a minimum driving current required for the signal amplifier part 20 in the bias part 10.

The bias part 10 and the signal amplifier part 20 are connected to receive a driving current generated from the bias part 10, amplify and process a signal input from the RF input and the second matching part 42, and transmit it to the RF output terminal and the first matching part 41, and in amplifying and processing the input signal, the signal amplified using the signal amplifier part 20 is attenuated and transmitted to a first transistor T1 of the signal amplifier part 20 so that the first transistor T1 and a second transistor T2 stably provide high gain amplification in a wide operating band.

The bias part 10 is configured to be connected to the RF output part, the power supply part, the first transistor T1, and the ground part as a self-bias structure and provides a driving current for the first transistor T1 by utilizing a current generated in accordance with a ratio of resistance values applied to a first resistor R1 and a second resistor R2.

By adding the diode D1 to a section connected to the first transistor T1 and the second resistor R2, a change in current which occurs in accordance with a change in resistance according to a temperature is utilized to compensate for a change in driving current of the first transistor T1 in accordance with a change in temperature.

The output stabilization part 30 provides stability in low-frequency bands and high-frequency bands by attenuating and feedback-attenuating an amplified signal generated from the first transistor T1 and the second transistor T2 of the signal amplifier part 20 and may block and isolate an inflow of noise and amplified signals from the power supply provided from the RF output.

Since the signal amplifier part 20 is based on a Darlington amplifier structure in which the emitter of the first transistor T1 is connected to the base of the second transistor T2, the current gains of the two transistors are multiplied to provide a large current gain so that a large output current may be controlled with a small base current. Here, since the two transistors T1 and T2 are connected in series, the emitter-base capacitance of the input transistor T1 is amplified by the current gain of the two transistors T1 and T2. This causes the Miller effect which limits the bandwidth of the circuit by lowering the overall input impedance, thereby reducing the amplification characteristics of the high-frequency band.

Thus, it is difficult to implement gain amplification uniformly. Therefore, the second regulator 52 is installed between the first transistor 1 and the second transistor T2 and the first regulator 51 is installed between the emitter and ground of the second transistor T2 to implement uniform gain amplification.

FIG. 4 is a diagram showing a circuit diagram of a low power broadband gain amplifier according to a third example embodiment of the present disclosure.

Referring to FIG. 4, a gain amplifier according to the third example embodiment is a gain amplifier which implements the output stabilization part 30, the first regulator 51, and the second regulator 52 of the gain amplifier according to the second example embodiment of FIG. 3 as a circuit.

The first regulator 51 improves the thermal stability and the bias stability of the second transistor T2 using a fifth resistor R5. It also increases the input impedance of the second transistor T2 to improve matching and reduces nonlinearity to improve linearity.

Additionally, the operating band amplification gain is stabilized through attenuation feedback with the common ground to suppress oscillation.

The second regulator 52 may be implemented by a combination of an inductor L and a sixth resistor R6 and this combination may be used for easily improving or adjusting the frequency response which may be used for improving the responsiveness at high frequencies or optimizing performance in a specific frequency band.

Also, the combination of the sixth resistor R6 and the inductor L may reduce the possibility of oscillation and increase the stability of the circuit through phase compensation so that the circuit may be operated with additional stability, particularly in high-frequency band amplification.

According to an example embodiment of the present disclosure, the amplified signal coupled at the output section exhibits a difference in gain amplification as the frequency increases from the low-frequency in intermediate frequency (IF) band to the high-frequency RF band.

Such differences increase the complexity and the cost of RF systems using gain amplifiers.

Thus, if a broadband gain amplifier provides uniform gain amplification across the operating band, the system configuration may be simplified and the configuration cost may be reduced.

Additionally, operating the broadband gain amplifier under low power conditions may reduce the required power consumption, which in turn may significantly reduce carbon dioxide emissions. In order to uniformly amplify signals from low IF frequency bands to high RF frequency bands, a regulator is connected to a part in which an output of the input transistor and an input of the output transistor are connected and a regulator is connected between an output transistor and the ground.

The gain amplifier which uniformly amplifies signals from low IF bands to high RF bands maintains signal quality and reduces distortion due to small gain change with frequency. This simplifies system design and reduces the number of components and costs.

In addition, the uniform gain characteristic reduces additional power consumption, thereby improving energy efficiency. These characteristics are suitable for applications supporting various frequency bands such as communications, radar, and satellite systems and enable high-quality and cost-effective system configurations.

FIG. 5 shows a response for each frequency of an amplifier composed of a Darlington circuit that is a basic structure of the first example embodiment of the present disclosure.

Referring to FIG. 5, a response for each frequency of an amplifier configured of a Darlington circuit that is a basic structure of the present disclosure may have a high gain as is the advantage of the Darlington structure, but the reduction in amplification gain by frequency of the operating band is high and the amplifier becomes unstable due to the high gain in the low-frequency band.

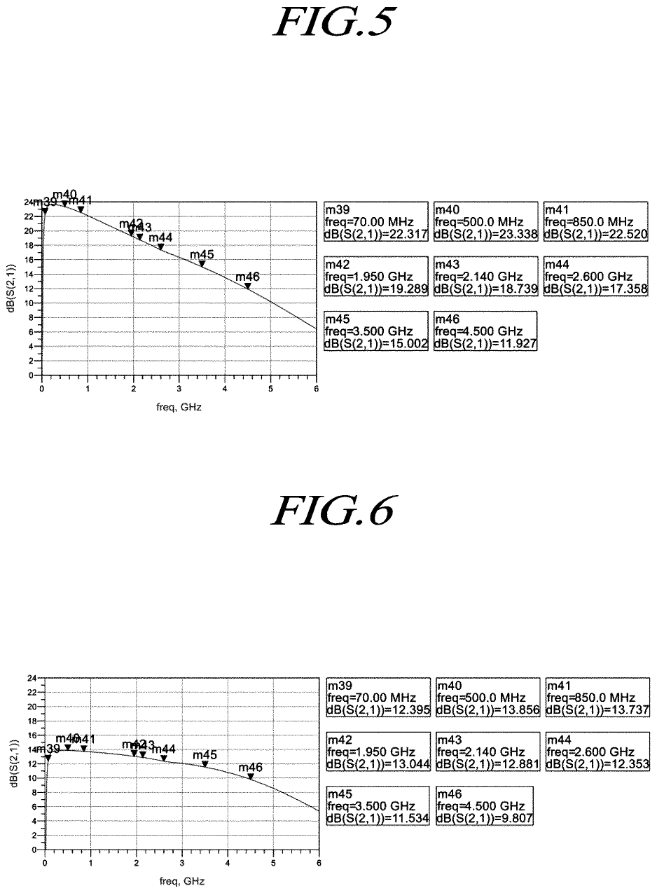

FIG. 6 shows a response for each frequency of a gain amplifier to which the first regulator 51 is applied in the second example embodiment of the present disclosure.

Referring to FIG. 6, the second example embodiment minimizes the difference in frequency response compared to the gain amplifier of the first example embodiment of FIG. 5, thereby attenuating unstable high gain in the low frequency band and further improving thermal stability and circuit stability.

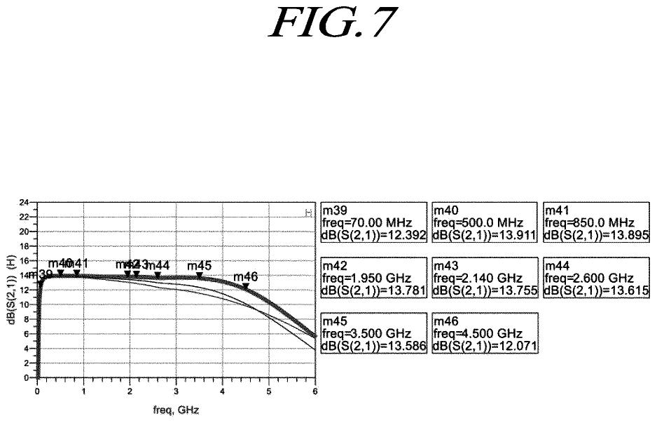

FIG. 7 shows a response for each frequency of a gain amplifier to which both of the first regulator 51 and the second regulator 52 are applied in the third example embodiment of the present disclosure.

Referring to FIG. 7, the results of increasing a response for each frequency of a representative gain amplifier according to the third example embodiment of the present disclosure are shown.

If the first regulator 51 attenuates the unstable high gain of the low frequency band of the gain amplifier and improves thermal stability, the second regulator 52 is added to increase the decreasing response by frequency, thereby implementing a very uniform amplification gain of the operating band.

Although an example embodiment of the present disclosure has been described in detail above, the scope of the present disclosure is not limited thereto and various modifications and improvements made by those skilled in the art using the basic concept of the present disclosure defined in the following claims are also included in the scope of the present disclosure.

What is claimed is:

1. A low power broadband gain amplifier, comprising:
a signal amplifier which amplifies and processes an input signal;
a bias part which provides a bias current for operating the signal amplifier part; and
an output stabilization part which attenuates and transmits an output signal of the signal amplifier part.

2. The low power broadband gain amplifier of claim 1, further comprising:
a first matching part which is connected to an output terminal of the signal amplifier; and
a second matching part which is connected to an input terminal of the signal amplifier.

3. The low power broadband gain amplifier of claim 2, wherein the bias part includes:
a first resistor which is connected to a radio frequency (RF) output and the first matching part, is connected to the first transistor and the output stabilization part, and is connected to an RF input and the second matching part;
a diode which is connected to the first resistor, is connected to the RF input and the second matching part, and is connected to a second resistor connected to a common ground; and
a second resistor which is connected to the diode and is connected to a common ground.

4. The low power broadband gain amplifier of claim 3, wherein the signal amplifier part includes:
a first transistor which amplifies an input signal, in which the RF output is connected to the first matching part and the RF input is connected to the second matching part;
a third resistor which is connected to an emitter of the first transistor and ensures heat dissipation and operational stability of the first transistor;
a second transistor which is connected to the RF output and the first matching part, preserves quality of a signal amplified from the first transistor, and additionally amplifies a gain;
a first regulator which is connected to an emitter of the second transistor, secures heat dissipation and operational stability of the second transistor, suppresses low-frequency oscillation to reduce operational instability, and uniformly adjusts flatness of amplification gain for each frequency; and
a second regulator which suppresses high-frequency oscillation of the first transistor to reduce instability of operation and is capable of evenly adjusting flatness of amplification gain for each frequency.

5. The low power broadband gain amplifier of claim 4, wherein the output stabilization part includes:
a fourth resistor which is connected to the first matching part connected to the RF output and is connected to the first resistor; and
a first capacitor which is connected to the fourth resistor and the first transistor and is connected to the first resistor and the diode.

6. The low power broadband gain amplifier of claim 5, wherein the first regulator improves thermal stability and bias stability of the second transistor using the fifth resistor.

7. The low power broadband gain amplifier of claim 6, wherein the second regulator is composed of a combination of an inductor and a sixth resistor.

8. The low power broadband gain amplifier of claim 1, wherein the bias part allows additional series connection of diodes to compensate for a voltage drop due to a change in temperature in the circuit, thereby stabilizing a change in driving current due to a change in temperature.
